(19) United States
(12) Patent Application Publication
(10) Pub. No.: US 2009/0233230 A1
(43) Pub. Date: Sep. 17, 2009

(54) Photosensitive Resin Composition and Laminates

(76) Inventors: Yosuke Hata, Tokyo (JP); Toru Mori, Tokyo (JP)

Correspondence Address: Finnegan, Henderson, Farabow, Garrett & Dunner,;L.L.P., 901 New York Avenue, N.W., Washington, DC, 20001-4413, US

(21) Appl. No.: 11/989,124

(22) PCT Filed: Jul. 22, 2005
(86) PCT No.: PCT/JP2005/013455

§ 371 Date: Jan. 22, 2008

(51) Int. Cl. G03F 7/20; G03F 7/004

(52) U.S. Cl. 430/285.1; 430/286.1; 430/325; 430/313; 430/315

(57) ABSTRACT

The present invention provides a photosensitive resin composition characterized by comprising: (a) 20 to 90% by mass of a thermoplastic copolymer comprising an α,β-unsaturated carboxyl group containing monomer as a copolymerization constituent and having an acid equivalent of 100 to 600 and a weight-average molecular weight of 5000 to 500000; (b) 5 to 75% by mass of an addition polymerizable monomer having at least one terminal ethylenic unsaturated group; (c) 0.01 to 30% by mass of a photopolymerization initiator containing a hexaarylbisimidazole; and (d) 0.001 to 10% by mass of a pyrazoline compound represented by the following general formula (I):

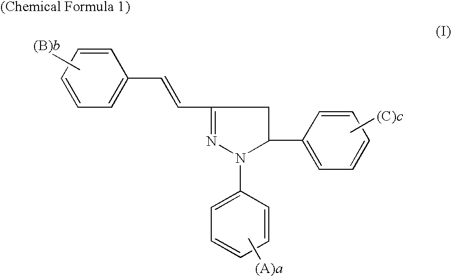

(wherein A, B, and C each independently represent a substituent selected from the group consisting of an aryl group, a heterocyclic group, a linear or branched alkyl group having 3 or more carbon atoms, and NR₂ (R represents a hydrogen atom or an alkyl group); and each of a, b, and c represents an integer of 0 to 2, provide that the value of a+b+c is 1 or larger).

### TECHNICAL FIELD

The present invention relates to a photosensitive resin composition that can be developed with an aqueous alkaline solution, a photosensitive resin layered film obtained by laminating the photosensitive resin composition onto a support, a method for forming a resist pattern on a base plate using the photosensitive resin layered film, and applications of the resist pattern. More specifically, the present invention relates to a photosensitive resin composition that provides a resist pattern preferable as a protective mask member in the production of a printed wiring board, the production of a flexible printed wiring board, the production of a lead frame for mounting an IC chip thereon (hereinafter, referred to as a lead frame), the precision processing of a metallic foil such as the production of a metal mask, the production of a semiconductor package such as BGA (Ball Grid Array) or CSP (Chip Size Package), the production of a tape substrate typified by TAB (Tape Automated Bonding) or COF (Chip On Film: semiconductor IC mounted on a fine wiring board in a film form), the production of a semiconductor bump, the production of a member such as an ITO electrode, an address electrode, or an electromagnetic shield in the field of a flat panel display, and the processing a substrate by a sandblast method.

### BACKGROUND ART

Heretofore, printed wiring boards have been produced by a photolithography method. The photolithography method refers to a method comprising: applying a photosensitive resin composition onto a base plate; performing pattern exposure; polymerizing and curing the exposed parts of the photosensitive resin composition; removing the unexposed parts with a developing solution to form a resist pattern on the base plate; forming a conductor pattern by etching or plating treatment; and then stripping and removing the resist pattern from the base plate to thereby form the conductor pattern on the base plate.

In the photolithography method, either of a method comprising applying a photoresist solution onto a base plate and drying the photoresist solution or a method comprising laminating, onto a base plate, a photosensitive resin layered film (hereinafter, referred to as a “dry film resist”) obtained by laminating a layer comprising a support and a photosensitive resin composition (hereinafter, referred to as a “a photosensitive resin layer”) and an optional protective layer in order is used for applying a photosensitive resin composition onto a base plate. In the production of a printed wiring board, the latter dry film resist is often used.

Hereinafter, a method for producing a printed wiring board using the dry film resist will be described simply.

When the dry film resist has a protective layer such as a polyethylene film, this protective layer is initially stripped from the photosensitive resin layer. Subsequently, the photosensitive resin layer and a support are laminated onto a base plate such as a copper clad laminate by use of a laminator so that the base plate, the photosensitive resin layer, and the support are provided in this order. Subsequently, the photosensitive resin layer is exposed via a photomask having a wiring pattern to UV rays such as i-rays (365 nm) emitted from an ultra-high-pressure mercury lamp to thereby polymerize and cure the exposed parts. Subsequently, the support made of polyethylene terephthalate or the like is stripped therefrom. Subsequently, the unexposed parts of the photosensitive resin layer are removed by dissolution or dispersion with a developing solution such as a weakly alkaline, aqueous solution to form a resist pattern on the base plate. Subsequently, the formed resist pattern is used as a protective mask to perform known etching or pattern plating treatment. Finally, the resist pattern is stripped from the base plate to produce a base plate having a conductive pattern, that is, a printed wiring board.

As the gaps between wiring lines in a printed wiring board have been finer in recent years, high resolution has been desired increasingly for the dry film resist. Moreover, high sensitivity has also been required for the dry film resist from the viewpoint of improving productivity. On the other hand, exposure methods have been diversified according to applications. Maskless exposure without the need of a photomask, such as direct writing using a laser has been expanded sharply in recent years. Light with a wavelength of 350 to 410 nm, particularly, i- or h-rays (405 nm) are often used as a light source in maskless exposure. Thus, an emphasis is placed on being capable of forming a resist pattern having high sensitivity and high resolution to these light sources within this wavelength range.

The absorption ranges of benzophenone and Michler's ketone, and their derivatives conventionally used as a photopolymerization initiator in a photosensitive resin composition for a dry film resist are localized to a wavelength around 360 nm. Thus, a dry film resist using the photopolymerization initiator has sufficient sensitivity to i-rays. However, the sensitivity is reduced as the wavelength of an exposure light source approach a visible region. It is difficult to obtain sufficient resolution and adhesion for a light source at 400 nm or more.

Moreover, thioxanthone and its derivatives as another photopolymerization initiator can be used as a combination exhibiting high sensitivity to an exposure light source with a wavelength around 380 nm by selecting an appropriate sensitizer. However, sufficient resolution is not obtained in the formed resist pattern in many cases even when the combination is used. Again, sensitivity is reduced to an exposure light source with a wavelength of 400 nm or more.

Japanese Patent Application Laid-Open No. 4-223470 (hereinafter, referred to as “Patent Document 1”) discloses hexaarylbisimidazole and 1,3-diaryl-pyrazoline or 1-aryl-3-aralkenyl-pyrazoline as photoinitiators having high photosensitivity and favorable image reproduction. Examples in which a dry film resist was formed are also described therein. However, the present inventor prepared a dry film photoresist having a photosensitive resin layer containing 1,5-diphenyl-3-styryl-pyrazoline and 1-phenyl-3-(4-methyl-styryl)-5-(4-methyl-phenyl)-pyrazoline as compounds specifically described in Patent Document 1. As a result, the compounds remained as undissolved matters in the photosensitive resin layer. This photosensitive resin layer could not be used as a dry film resist. Details thereof are shown in Comparative Example described later.

Alternatively, Japanese Patent No. 2931693 (hereinafter, referred to as “Patent Document 2”) discloses a light-shielding agent comprising a pyrazoline compound having a particular substituent introduced into 1,5-diphenyl-3-styryl-pyrazoline. Examples in which a photoresist solution supplemented with the pyrazoline compound was applied to a base plate are also described therein. However, the light-shielding agent described in Patent Document 2 is an additive used for preventing resolution from being reduced due to the sensitization of even a portion supposed to be an unexposed part by reflected light from the base plate on exposure. Patent Document 2 does not state that the pyrazoline compound is used as a sensitizer for a photopolymerization initiator of a dry film resist.

For such reasons, a photosensitive resin composition that exhibits favorable compatibility and is excellent in sensitivity and resolution particularly to a light source at 400 nm or more, in adhesion, and in storage stability has been demanded as a photosensitive resin composition for a dry film resist.

Patent Document 1: Japanese Patent Application Laid-Open No. 4-223470

Patent Document 2: Japanese Patent No. 2931693

### DISCLOSURE OF THE INVENTION

An object of the present invention is to provide a photosensitive resin composition that has favorable compatibility in the preparation of a dry film, excellent sensitivity and resolution to an exposure light source having a wavelength of 350 to 410 nm, excellent adhesion, and favorable storage stability and can be developed with an aqueous alkaline solution, a photosensitive resin layered film using the photosensitive resin composition, a method for forming a resist pattern on a base plate using the photosensitive resin layered film, and applications of the resist pattern.

The object can be achieved by the following constitution of the present invention:

(1) A photosensitive resin composition characterized by comprising: (a) 20 to 90% by mass of a thermoplastic copolymer comprising an α,β-unsaturated carboxyl group containing monomer as a copolymerization constituent and having an acid equivalent of 100 to 600 and a weight-average molecular weight of 5000 to 500000; (b) 5 to 75% by mass of an addition polymerizable monomer having at least one terminal ethylenic unsaturated group; (c) 0.01 to 30% by mass of a photopolymerization initiator containing a hexaarylbisimidazole; and (d) 0.001 to 10% by mass of a pyrazoline compound represented by the following general formula (I):

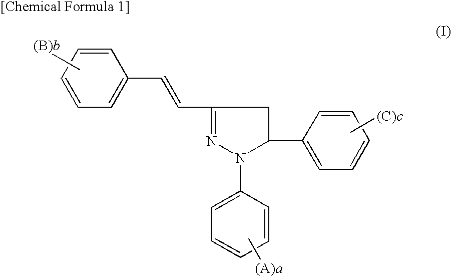

(wherein A, B, and C each independently represent a substituent selected from the group consisting of an aryl group, a heterocyclic group, a linear or branched alkyl group having 3 or more carbon atoms, and NR₂ (R represents a hydrogen atom or an alkyl group); and each of a, b, and c represents an integer of 0 to 2, provide that the value of a+b+c is 1 or larger).

(2) The photosensitive resin composition according to (1), wherein the pyrazoline compound (d) is a pyrazoline compound represented by the following general formula (I):

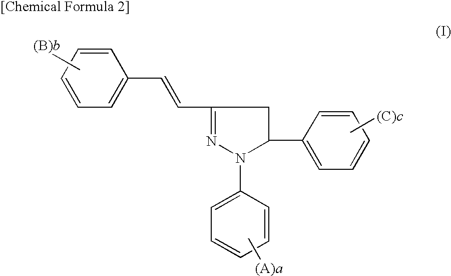

(wherein B and C each independently represent a linear or branched alkyl group having 3 or more carbon atoms, or NR₂ (R represents a hydrogen atom or an alkyl group); A represents a substituent selected from the group consisting of an aryl group, a heterocyclic group, and a linear or branched alkyl group having 3 or more carbon atoms; a represents 0 or 1, and b and c represent b=c=1).

(3) The photosensitive resin composition according to (1), characterized in that the pyrazoline compound (d) comprises 1-phenyl-3-(4-tert-butyl-styryl)-5-(4-tert-butyl-phenyl)-pyrazoline or 1-(4-(benzoxazol-2-yl)phenyl)-3-(4-tert-butyl-styryl)-5-(4-tert-butyl-phenyl)-pyrazoline, or a mixture thereof.

(4) The photosensitive resin composition according to any of (1) to (3), characterized in that the addition polymerizable monomer (b) contains a compound represented by the following general formula (II) or a compound represented by the following general formula (III), or a mixture thereof:

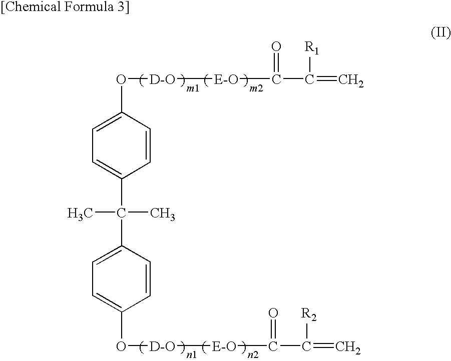

(wherein each of R₁ and R₂, which may be the same or different, represents H or CH₃; each of D and E, which may be the same or different, represents an alkylene group having 2 to 4 carbon atoms, and when D and E are different, -(D-O)— and -(E-O)— repeating units may have a block or random structure; and each of m1, m2, n1, and n2 represents 0 or a positive integer, and the sum of m1, m2, n1, and n2 is 2 to 30), and

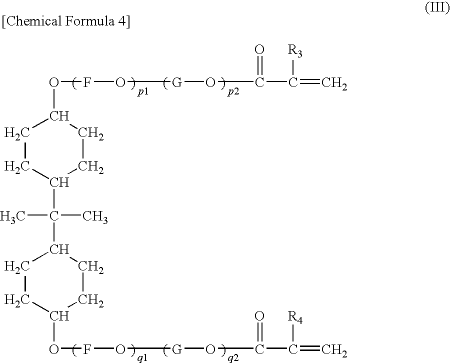

(wherein each of R₃ and R₄, which may be the same or different, represents H or CH₃; each of F and G, which may be the same or different, represents an alkylene group having 2 to 4 carbon atoms, and when F and G are different, —(F—O)— and -(G-O)— repeating units may have a block or random structure; and each of p1, p2, q1, and q2 represents 0 or a positive integer, and the sum of p1, p2, q1, and q2 is 2 to 30).

(5) A photosensitive resin layered film obtained by laminating a photosensitive resin composition according to any of (1) to (4) onto a support.

(6) A method for forming a resist pattern, comprising a lamination step of forming a photosensitive resin layer on a base plate using a photosensitive resin layered film according to (5), an exposure step, and a development step.

(7) The method for forming a resist pattern according to (6), characterized in that at the exposure step, the exposure is performed by direct writing.

(8) A method for producing a printed wiring board, comprising the step of etching or plating a base plate having a resist pattern formed by a method according to (6) or (7).

(9) A method for producing a lead frame, comprising the step of etching a base plate having a resist pattern formed by a method according to (6) or (7).

(10) A method for producing a semiconductor package, comprising the step of etching or plating a base plate having a resist pattern formed by a method according to (6) or (7).

(11) A method for producing a substrate having a concavo-convex pattern, comprising the step of processing, by sandblast, a base plate having a resist pattern formed by a method according to (6) or (7).

The photosensitive resin composition of the present invention has favorable compatibility in the preparation of a dry film resist and high sensitivity to an exposure light source having a wavelength of 350 to 410 nm. Moreover, the photosensitive resin layered film of the present invention has excellent sensitivity on exposure, excellent resolution and adhesion of a resist pattern after development, and favorable storage stability. The method for forming a resist pattern according to the present invention provides a resist pattern excellent in sensitivity, resolution, and adhesion and can be used preferably in the production of a printed wiring board, the production of a lead frame, the production of a semiconductor package, and the production of a flat display.

### BEST MODE FOR CARRYING OUT THE INVENTION

Hereinafter, the present invention will be described specifically.

### <Photosensitive Resin Composition>

A photosensitive resin composition of the present invention comprises, as essential constituents: (a) 20 to 90% by mass of a thermoplastic copolymer comprising an α,β-unsaturated carboxyl group containing monomer as a copolymerization constituent and having an acid equivalent of 100 to 600 and a weight-average molecular weight of 5000 to 500000; (b) 5 to 75% by mass of an addition polymerizable monomer having at least one terminal ethylenic unsaturated group; (c) 0.01 to 30% by mass of a photopolymerization initiator containing a hexaarylbisimidazole; and (d) 0.001 to 10% by mass of a pyrazoline compound represented by the following general formula (I):

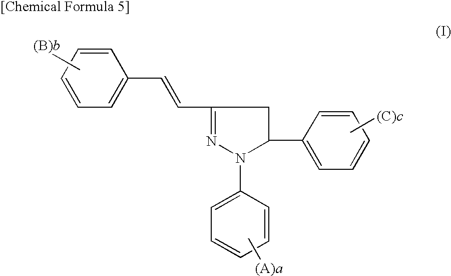

(wherein A, B, and C each independently represent a substituent selected from the group consisting of an aryl group, a heterocyclic group, a linear or branched alkyl group having 3 or more carbon atoms, and NR₂ (R represents a hydrogen atom or an alkyl group); and each of a, b, and c represents an integer of 0 to 2, provide that the value of a+b+c is 1 or larger).

(a) Thermoplastic Copolymer

In the photosensitive resin composition of the present invention, a thermoplastic copolymer comprising an α,β-unsaturated carboxyl group containing monomer as a copolymerization constituent and having an acid equivalent of 100 to 600 and a weight-average molecular weight of 5000 to 500000 is used as the thermoplastic copolymer (a).

The carboxyl group in the thermoplastic copolymer is required for the photosensitive resin composition to have developability or strippability for a developing or stripping solution made of an aqueous alkaline solution. The acid equivalent is preferably 100 to 600, more preferably 300 to 450. The acid equivalent is 100 or higher from the viewpoint of securing compatibility with a solvent or with other constituents in the composition, particularly, the addition polymerizable monomer (b) described later and is 600 or lower from the viewpoint of maintaining developability and strippability. In this context, the acid equivalent refers to the mass (gram) of the thermoplastic copolymer having 1 equivalent carboxyl group therein. The measurement of the acid equivalent is performed by a potentiometric titration method in a 0.1 mol/L aqueous solution of NaOH using Hiranuma Reporting Titrator (COM-555).

The weight-average molecular weight is preferably 5000 to 500000. The weight-average molecular weight is 5000 or higher from the viewpoint of uniformly maintaining the thickness of a dry film resist and obtaining resistance to a developing solution and is 500000 or lower from the viewpoint of maintaining developability. More preferably, the weight-average molecular weight is 20000 to 100000. In this case, the weight-average molecular weight refers to a weight-average molecular weight measured by gel permeation chromatography (GPC) using a calibration curve of polystyrene. The weight-average molecular weight can be measured using gel permeation chromatography manufactured by JASCO Corp. according to the following conditions:

Differential refractometer: RI-1530

Pump: PU-1580

Degasser: DG-980-50

Column oven: CO-1560

Column: KF-8025, KF-806Mx2, and KF-807 in this order

Eluant: THF

It is preferred that the thermoplastic copolymer should be a copolymer comprising at least one or more of first monomers described below or a copolymer comprising at least one or more of the first monomers and at least one or more of second monomers described later.

The first monomers are monomers containing an α,β-unsaturated carboxyl group in the molecule. Examples thereof include (meth)acrylic acid, fumaric acid, cinnamic acid, crotonic acid, itaconic acid, maleic anhydrides, and a half ester of maleic acid. Among them, (meth)acrylic acid is particularly preferable.

The second monomers are non-acidic monomers having at least one polymerizable unsaturated group in the molecule. Examples thereof include methyl (meth)acrylate, ethyl(meth)acrylate, n-propyl(meth)acrylate, iso-propyl (meth)acrylate, n-butyl(meth)acrylate, iso-butyl(meth)acrylate, tert-butyl (meth)acrylate, 2-hydroxyethyl(meth)acrylate, 2-hydroxypropyl(meth)acrylate, 2-ethylhexyl(meth)acrylate, benzyl(meth)acrylate, esters of vinyl alcohols such as vinyl acetate, (meth)acrylonitrile, styrene, and polymerizable styrene derivatives. Among them, methyl(meth)acrylate, n-butyl(meth)acrylate, styrene, and benzyl (meth)acrylate are particularly preferable.

The amount of the thermoplastic polymer contained in the photosensitive resin composition of the present invention ranges from 20 to 90% by mass, preferably 25 to 70% by mass. This amount is 20% by mass or more from the viewpoint of maintaining alkali developability and is 90% by mass or less from the viewpoint of sufficiently exerting the resist performance of a resist pattern formed by exposure.

(b) Addition Polymerizable Monomer

It is desired from the viewpoint of resolution and adhesion that the addition polymerizable monomer (b) used in the photosensitive resin composition of the present invention should contain a compound represented by the following general formula (II):

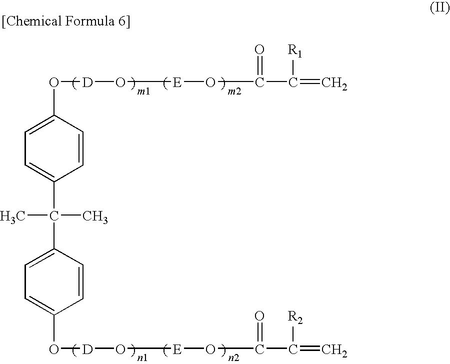

(wherein each of R₁ and R₂, which may be the same or different, represents H or CH₃; each of D and E, which may be the same or different, represents an alkylene group having 2 to 4 carbon atoms, and when D and E are different, -(D-O)— and -(E-O)— repeating units may have a block or random structure; and each of m1, m2, n1, and n2 represents 0 or a positive integer, and the sum of m1, m2, n1, and n2 is 2 to 30).

Examples of the compound represented by the general formula (II) include 2,2-bis{(4-acryloxypolyethoxy)phenyl}propane and 2,2-bis{(4-methacryloxypolyethoxy)phenyl}propane. It is preferred that the polyethoxy group in the compound should be any group selected from the group consisting of monoethoxy, diethoxy, triethoxy, tetraethoxy, pentaethoxy, hexaethoxy, heptaethoxy, octaethoxy, nonaethoxy, decaethoxy, undecaethoxy, dodecaethoxy, tridecaethoxy, tetradecaethoxy, and pentadecaethoxy groups. Alternative examples of the compound include 2,2-bis{(4-acryloxypolyalkyleneoxy)phenyl}propane and 2,2-bis{(4-methacryloxypolyalkyleneoxy)phenyl}propane. Examples of the polyalkyleneoxy group in the compound include a mixture of ethoxy and propyloxy groups. A block or random adduct of octaethoxy and dipropyloxy groups and a block or random adduct of tetraethoxy and tetrapropyloxy groups are preferable. Among them, 2,2-bis {(4-methacryloxypentaethoxy)phenyl}propane is most preferable.

It is also desired from the viewpoint of resolution that the photosensitive resin composition of the present invention should comprise a compound represented by the following general formula (III) as the addition polymerizable monomer (b):

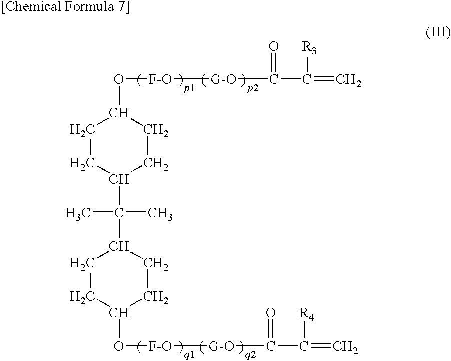

(wherein each of R₃ and R₄, which may be the same or different, represents H or CH₃; each of F and G, which may be the same or different, represents an alkylene group having 2 to 4 carbon atoms, and when F and G are different, —(F—O)— and -(G-O)— repeating units may have a block or random structure; and each of p1, p2, q1, and q2 represents 0 or a positive integer, and the sum of p1, p2, q1, and q2 is 2 to 30).

Examples of the compound represented by the general formula (III) include 2,2-bis{(4-acryloxypolyethoxy)cyclohexyl}propane and 2,2-bis{(4-methacryloxypolyethoxy)cyclohexyl}propane. It is preferred that the polyethoxy group in the compound should be any group selected from the group consisting of monoethoxy, diethoxy, triethoxy, tetraethoxy, pentaethoxy, hexaethoxy, heptaethoxy, octaethoxy, nonaethoxy, decaethoxy, undecaethoxy, dodecaethoxy, tridecaethoxy, tetradecaethoxy, and pentadecaethoxy groups. Alternative examples of the compound include 2,2-bis{(4-acryloxypolyalkyleneoxy)cyclohexyl}propane and 2,2-bis{(4-methacryloxypolyalkyleneoxy)cyclohexyl}propane. Examples of the polyalkyleneoxy group in the compound include a mixture of ethoxy and propyloxy groups. A block or random adduct of octaethoxy and dipropyloxy groups and a block or random adduct of tetraethoxy and tetrapropyloxy groups are preferable. Among them, 2,2-bis{(4-methacryloxypentaethoxy)cyclohexyl}propane is most preferable.

When the compound represented by the general formula (II) or (III) is contained in the photosensitive resin composition of the present invention, it is preferred that the compound should be contained in an amount of 5 to 40% by mass, more preferably 10 to 30% by mass, in the photosensitive resin composition. This amount is 5% by mass or more from the viewpoint of exhibiting high resolution and high adhesion and is 40% by mass or less from the viewpoint of suppressing cold flow and delay in the stripping of a cured resist.

A known compound having at least one terminal ethylenic unsaturated group, other than the compound described above can be used as the addition polymerizable monomer (b) used in the photosensitive resin composition of the present invention.

Examples thereof include 4-nonylphenylheptaethylene glycol dipropylene glycol acrylate, 2-hydroxy-3-phenoxypropyl acrylate, phenoxyhexaethylene glycol acrylate, a reaction product of a half ester compound of a phthalic anhydride and 2-hydroxypropyl acrylate with propylene oxide (manufactured by Nippon Shokubai Co., Ltd., trade name: OE-A 200), 4-normaloctylphenoxypentapropylene glycol acrylate, 2,2-bis[{4-(meth)acryloxypolyethoxy}phenyl]propane, 1,6-hexanediol (meth)acrylate, 1,4-cyclohexanediol di(meth)acrylate, polyoxyalkylene glycol di(meth)acrylate such as polypropylene glycol di(meth)acrylate, polyethylene glycol di(meth)acrylate, and polyoxyethylene polyoxyprolylene glycol di(meth)acrylate, 2-di(p-hydroxyphenyl)propane di(meth)acrylate, glycerol tri(meth)acrylate, pentaerythritol penta(meth)acrylate, trimethylolpropane triglycidyl ether tri(meth)acrylate, 2,2-bis(4-methacryloxypentaethoxyphenyl)propane, multifunctional group (meth)acrylate containing an urethane group, such as an urethanized product of hexamethylene diisocyanate and nonapropylene glycol monomethacrylate, and multifunctional (meth)acrylate of an isocyanuric acid ester compound. These compounds may be used alone or in combination of two or more of them.

The amount of the addition polymerizable monomer (b) contained in the photosensitive resin composition of the present invention ranges from 5 to 75% by mass, more preferably 15 to 70% by mass. This amount is 5% by mass or more from the viewpoint of suppressing poor curing and delay in developing time and is 75% by mass or less from the viewpoint of suppressing cold flow and delay in the stripping of a cured resist.

(c) Photopolymerization Initiator

The photosensitive resin composition of the present invention comprises the photopolymerization initiator (c), which contains a hexaarylbisimidazole (hereinafter, also referred to as a triarylimidazolyl dimer) as an essential constituent.

The amount of the photopolymerization initiator (c) contained in the photosensitive resin composition of the present invention ranges from 0.01 to 30% by mass, more preferably 0.05 to 10% by mass. This amount is preferably 0.01% by mass or more from the viewpoint of obtaining sufficient sensitivity and is preferably 30% by mass or less from the viewpoint of sufficiently transmitting light to the bottom surface of a resist and obtaining favorable, high resolution and adhesion.

Examples of the triarylimidazolyl dimer include 2-(o-chlorophenyl)-4,5-diphenylimidazolyl dimer (hereinafter, also referred to as 2,2′-bis(2-chlorophenyl)-4,4′,5,5′-tetraphenyl-1,1′-bisimidazole), 2,2′,5-tris-(o-chlorophenyl)-4-(3,4-dimethoxyphenyl)-4′,5′-diphenylimidazolyl dimer, 2,4-bis-(o-chlorophenyl)-5-(3,4-dimethoxyphenyl)-diphenylimidazolyl dimer, 2,4,5-tris-(o-chlorophenyl)-diphenylimidazolyl dimer, 2-(o-chlorophenyl)-bis-4,5-(3,4-dimethoxyphenyl)-imidazolyl dimer, 2,2′-bis-(2-fluorophenyl)-4,4′,5,5′-tetrakis-(3-methoxyphenyl)-imidazolyl dimer, 2,2′-bis-(2,3-difluoromethylphenyl)-4,4′,5,5′-tetrakis-(3-methoxyphenyl)-imidazolyl dimer, 2,2′-bis-(2,4-difluorophenyl)-4,4′,5,5′-tetrakis-(3-methoxyphenyl)-imidazolyl dimer, 2,2′-bis-(2,5-difluorophenyl)-4,4′,5,5′-tetrakis-(3-methoxyphenyl)-imidazolyl dimer, 2,2′-bis-(2,6-difluorophenyl)-4,4′,5,5′-tetrakis-(3-methoxyphenyl)-imidazolyl dimer, 2,2′-bis-(2,3,4-trifluorophenyl)-4,4′,5,5′-tetrakis-(3-methoxyphenyl)-imidazolyl dimer, 2,2′-bis-(2,3,5-trifluorophenyl)-4,4′,5,5′-tetrakis-(3-methoxyphenyl)-imidazolyl dimer, 2,2′-bis-(2,3,6-trifluorophenyl)-4,4′,5,5′-tetrakis-(3-methoxyphenyl)-imidazolyl dimer, 2,2′-bis-(2,4,5-trifluorophenyl)-4,4′,5,5′-tetrakis-(3-methoxyphenyl)-imidazolyl dimer, 2,2′-bis-(2,4,6-trifluorophenyl)-4,4′,5,5′-tetrakis-(3-methoxyphenyl)-imidazolyl dimer, 2,2′-bis-(2,3,4,5-tetrafluorophenyl)-4,4′,5,5′-tetrakis-(3-methoxyphenyl)-imidazolyl dimer, 2,2′-bis-(2,3,4,6-tetrafluorophenyl)-4,4′,5,5′-tetrakis-(3-methoxyphenyl)-imidazolyl dimer, and 2,2′-bis-(2,3,4,5,6-pentafluorophenyl)-4,4′,5,5′-tetrakis-(3-methoxyphenyl)-imidazolyl dimer. Particularly, 2-(o-chlorophenyl)-4,5-diphenylimidazolyl dimer is a photopolymerization initiator having high effects on resolution and the strength of a cured film and is preferably used.

These photopolymerization initiators are used alone or in combination of two or more of them.

The amount of hexaarylbisimidazole contained in the photosensitive resin composition of the present invention is 0.01 to 30% by mass, preferably 0.05 to 10% by mass, most preferably 0.1 to 5% by mass. This amount needs to be 0.01% by mass or more from the viewpoint of obtaining sufficient sensitivity and is 30% by mass or less from the viewpoint of maintaining high resolution.

Moreover, a photopolymerization initiator other than hexaarylbisimidazole may be used in combination therewith in the photosensitive resin composition of the present invention. Examples of such a photopolymerization initiator include quinones such as 2-ethylanthraquinone, octaethylanthraquinone, 1,2-benzanthraquinone, 2,3-benzanthraquinone, 2-phenylanthraquinone, 2,3-diphenylanthraquinone, 1-chloroanthraquinone, 1,4-naphthoquinone, 9,10-phenanthraquinone, 2-methyl-1,4-naphthoquinone, 2,3-dimethylanthraquinone, and 3-chloro-2-methylanthraquinone, aromatic ketones such as benzophenone, Michler's ketone [4,4′-bis(dimethylamino)benzophenone], and 4,4′-bis(diethylamino)benzophenone, benzoin ethers such as benzoin, benzoin ethyl ether, benzoin phenyl ether, methylbenzoin, and ethylbenzoin, benzyl dimethyl ketal, benzyl diethyl ketal, N-phenylglycines such as N-phenylglycine, N-methyl-N-phenylglycine, and N-ethyl-N-phenylglycine, combinations of thioxanthones and alkylaminobenzoic acids, acridines such as 9-phenylacridine, and oxime esters such as 1-phenyl-1,2-propanedione-2-O-benzoinoxime and 1-phenyl-1,2-propanedione-2-(O-ethoxycarbonyl)oxime. Examples of the combinations of thioxanthones and alkylaminobenzoic acids include a combination of ethylthioxanthone and ethyl dimethylaminobenzoate, a combination of 2-chlorothioxanthone and ethyl dimethylaminobenzoate, and a combination of isopropylthioxanthone and ethyl dimethylaminobenzoate.

Preferable examples of the photopolymerization initiator other than hexaarylbisimidazole added to the photosensitive resin composition of the present invention can include thioxanthones such as diethylthioxanthone and chlorothioxanthone, dialkylaminobenzoic esters such as ethyl dimethylaminobenzoate, benzophenone, Michler's ketone, 4,4′-bis(diethylamino)benzophenone, 9-phenylacridine, N-phenylglycines, and combinations thereof. Among them, Michler's ketone or 4,4′-bis(diethylamino)benzophenone is particularly preferable.

(d) Pyrazoline Compound

The pyrazoline compound (d) as an essential constituent in the photosensitive resin composition of the present invention is a pyrazoline compound represented by the following general formula (I):

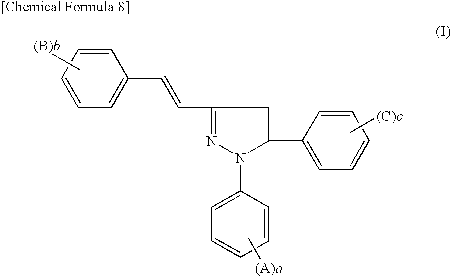

(wherein A, B, and C each independently represent a substituent selected from the group consisting of an aryl group, a heterocyclic group, a linear or branched alkyl group having 3 or more carbon atoms, and NR₂ (R represents a hydrogen atom or an alkyl group); and each of a, b, and c represents an integer of 0 to 2, provide that the value of a+b+c is 1 or larger).

Examples of the pyrazoline compound represented by the general formula (I) include 1-(4-tert-butyl-phenyl)-3-styryl-5-phenyl-pyrazoline, 1-phenyl-3-(4-tert-butyl-styryl)-5-(4-tert-butyl-phenyl)-pyrazoline, 1,5-bis(4-tert-butyl-phenyl)-3-(4-tert-butyl-styryl)-pyrazoline, 1-(4-tert-octyl-phenyl)-3-styryl-5-phenyl-pyrazoline, 1-phenyl-3-(4-tert-butyl-styryl)-5-(4-ethoxy-phenyl)-pyrazoline, 1-phenyl-3-(4-tert-octyl-styryl)-5-(4-tert-octyl-phenyl)-pyrazoline, 1,5-bis-(4-tert-octyl-phenyl)-3-(4-tert-octyl-styryl)-pyrazoline, 1-(4-dodecyl-phenyl)-3-styryl-5-phenyl-pyrazoline, 1-phenyl-3-(4-dodecyl-styryl)-5-(4-dodecyl-phenyl)-pyrazoline, 1-(4-dodecyl-phenyl)-3-(4-dodecyl-styryl)-5-(4-dodecyl-phenyl)-pyrazoline, 1-(4-tert-octyl-phenyl)-3-(4-tert-butyl-styryl)-5-(4-tert-butyl-phenyl)-pyrazoline, 1-(4-tert-butyl-phenyl)-3-(4-tert-octyl-styryl)-5-(4-tert-octyl-phenyl)-pyrazoline, 1-(4-dodecyl-phenyl)-3-(4-tert-butyl-styryl)-5-(4-tert-butyl-phenyl)-pyrazoline, 1-(4-tert-butyl-phenyl)-3-(4-dodecyl-styryl)-5-(4-dodecyl-phenyl)-pyrazoline, 1-(4-dodecyl-phenyl)-3-(4-tert-octyl-styryl)-5-(4-tert-octyl-phenyl)-pyrazoline, 1-(4-tert-octyl-phenyl)-3-(4-dodecyl-styryl)-5-(4-dodecyl-phenyl)-pyrazoline, 1-(2,4-dibutyl-phenyl)-3-(4-dodecyl-styryl)-5-(4-dodecyl-phenyl)-pyrazoline, 1-phenyl-3-(3,5-di-tert-butyl-styryl)-5-(3,5-di-tert-butyl-phenyl)-pyrazoline,
1-phenyl-3-(2,6-di-tert-butyl-styryl)-5-(2,6-di-tert-butyl-phenyl)-pyrazoline, 1-phenyl-3-(2,5-di-tert-butyl-styryl)-5-(2,5-di-tert-butyl-phenyl)-pyrazoline, 1-phenyl-3-(2,6-di-n-butyl-styryl)-5-(2,6-di-n-butyl-phenyl)-pyrazoline, 1-(3,4-di-tert-butyl-phenyl)-3-styryl-5-phenyl-pyrazoline, 1-(3,5-di-tert-butyl-phenyl)-3-styryl-5-phenyl-pyrazoline, 1-(4-tert-butyl-phenyl)-3-(3,5-di-tert-butyl-phenyl)-5-phenyl-pyrazoline, 1-(3,5-di-tert-butyl-phenyl)-3-(3,5-di-tert-butyl-styryl)-5-(3,5-di-tert-butyl-phenyl)-pyrazoline, 1-(4-(5-tert-butyl-benzoxazol-2-yl)phenyl)-3-styryl-5-phenyl-pyrazoline, 1-(4-(benzoxazol-2-yl)phenyl)-3-(4-tert-butyl-styryl)-5-(4-tert-butyl-phenyl)-pyrazoline, 1-(4-(4-tert-butyl-benzoxazol-2-yl)phenyl)-3-(4-tert-butyl-styryl)-5-(4-tert-butyl-phenyl)-pyrazoline, 1-(4-(5-tert-octyl-benzoxazol-2-yl)phenyl)-3-styryl-5-phenyl-pyrazoline, 1-(4-(benzoxazol-2-yl)phenyl)-3-(4-tert-octyl-styryl)-5-(4-tert-octyl-phenyl)-pyrazoline, 1-(4-(5-tert-octyl-benzoxazol-2-yl)phenyl)-3-(4-tert-octyl-styryl)-5-(4-tert-octyl-phenyl)-pyrazoline,
1-(4-(5-dodecyl-benzoxazol-2-yl)phenyl)-3-styryl-5-phenyl-pyrazoline, 1-(4-(benzoxazol-2-yl)phenyl)-3-(4-dodecyl-styryl)-5-(4-dodecyl-phenyl)-pyrazoline, 1-(4-(5-dodecyl-benzoxazol-2-yl)phenyl)-3-(4-dodecyl-styryl)-5-(4-dodecyl-phenyl)-pyrazoline, 1-(4-(5-tert-octyl-benzoxazol-2-yl)phenyl)-3-(4-tert-butyl-styryl)-5-(4-tert-butyl-phenyl)-pyrazoline, 1-(4-(5-tert-butyl-benzoxazol-2-yl)phenyl)-3-(4-tert-octyl-styryl)-5-(4-tert-octyl-phenyl)-pyrazoline, 1-(4-(5-dodecyl-benzoxazol-2-yl)phenyl)-3-(4-tert-butyl-styryl)-5-(4-tert-butyl-phenyl)-pyrazoline, 1-(4-(5-tert-butyl-benzoxazol-2-yl)phenyl)-3-(4-dodecyl-styryl)-5-(4-dodecyl-phenyl)-pyrazoline,
1-(4-(5-dodecyl-benzoxazol-2-yl)phenyl)-3-(4-tert-octyl-styryl)-5-(4-tert-octyl-phenyl)-pyrazoline, 1-(4-(5-tert-octyl-benzoxazol-2-yl)phenyl)-3-(4-dodecyl-styryl)-5-(4-dodecyl-phenyl)-pyrazoline, 1-(4-(4,6-dibutyl-benzoxazol-2-yl)phenyl)-3-(4-dodecyl-styryl)-5-(4-dodecyl-phenyl)-pyrazoline, 1-(4-(benzoxazol-2-yl)phenyl)-3-(3,5-di-tert-butylstyryl)-5-(3,5-di-tert-butyl-phenyl)-pyrazoline, 1-(4-(benzoxazol-2-yl)phenyl)-3-(2,6-di-tert-butyl-styryl)-5-(2,6-di-tert-butyl-phenyl)-pyrazoline,
1-(4-(benzoxazol-2-yl)phenyl)-3-(2,5-di-tert-butyl-styryl)-5-(2,5-di-tert-butyl-phenyl)-pyrazoline, 1-(4-(benzoxazol-2-yl)phenyl)-3-(2,6-di-n-butyl-styryl)-5-(2,6-di-n-butyl-phenyl)-pyrazoline, 1-(4-(4,6-di-tert-butyl-benzoxazol-2-yl)phenyl)-3-styryl-5-phenyl-pyrazoline, 1-(4-(5,7-di-tert-butyl-benzoxazol-2-yl)phenyl)-3-styryl-5-phenyl-pyrazoline, 1-(4-(5-tert-butyl-benzoxazol-2-yl)phenyl)-3-(3,5-di-tert-butyl-styryl)-5-phenyl-pyrazoline, 1-(4-(4,6-di-tert-butyl-benzoxazol-2-yl)phenyl)-3-(3,5-di-tert-butyl-styryl)-5-(3,5-di-tert-butyl-phenyl)-pyrazoline, 1-phenyl-3-(4-tert-butyl-styryl)-5-(4-amino-phenyl)-pyrazoline, 1-phenyl-3-(4-tert-butyl-styryl)-5-(4-N-ethyl-phenyl)-pyrazoline, and 1-phenyl-3-(4-tert-butyl-styryl)-5-(4-N,N-diethyl-phenyl)-pyrazoline.

Among the pyrazoline compounds represented by the general formula (I), pyrazoline compounds represented by the general formula (I) wherein B or C or both B and C have a tert-butyl group are more preferable. Among them, 1-phenyl-3-(4-tert-butyl-styryl)-5-(4-tert-butyl-phenyl)-pyrazoline is particularly preferable. Pyrazoline compounds having a benzoxazole group are particularly preferable for an exposure light source with a wavelength of 400 nm or more preferably used in maskless exposure. Among them, 1-(4-(benzoxazol-2-yl)phenyl)-3-(4-tert-butyl-styryl)-5-(4-tert-butyl-phenyl)-pyrazoline is particularly preferable.

The photosensitive resin composition of the present invention may contain one or more of the compounds represented by the general formula (I). The total amount thereof is 0.001 to 10% by mass. A more preferable range is 0.005 to 5% by mass. The most preferable range is 0.05 to 2% by mass. This amount is 0.001% by mass or more from the viewpoint of improving sensitivity and resolution and is 10% by mass or less from the viewpoint of improving compatibility with the thermoplastic polymer and the addition polymerizable monomer having a terminal ethylenic unsaturated group and dispersibility and exerting dry film photoresist effects.

In addition to the pyrazoline compound represented by the general formula (I), an additional pyrazoline compound may also be used in combination therewith in the photosensitive resin composition of the present invention. Examples of such a compound include 1-phenyl-3-(4-tert-butyl-styryl)-5-(4-carboxy-phenyl)-pyrazoline, 1-phenyl-3-(4-tert-butyl-styryl)-5-(4-mercapto-phenyl)-pyrazoline, 1-phenyl-3-(4-tert-butyl-styryl)-5-(4-hydroxy-phenyl)-pyrazoline, 1-phenyl-3-(4-tert-butyl-styryl)-5-(4-ethylthio-phenyl)-pyrazoline, and 1-phenyl-3-(4-tert-butyl-styryl)-5-(4-ethoxycarbonyl-phenyl)-pyrazoline.

In the photosensitive resin composition of the present invention, the pyrazoline compound (d) exerts sensitizer effects when used in combination with the photopolymerization initiator (c) containing a hexaarylbisimidazole.

(e) Additional Constituents

In addition to the constituents described above, coloring substances such as dyestuffs and pigments can be adopted in the photosensitive resin composition of the present invention. Examples of such coloring substances include phthalocyanine green, crystal violet, methyl orange, Nile blue 2B, victoria blue, malachite green, basic blue 20, and diamond green.

A color former may be added into the photosensitive resin composition of the present invention so that visible images can be provided by exposure. Examples of such color-forming dyestuffs include a leuco dye and combinations of fluoran dyes and halogen compounds. Examples of the halogen compounds include amyl bromide, isoamyl bromide, isobutylene bromide, ethylene bromide, diphenylmethyl bromide, benzal bromide, methylene bromide, tribromomethyl phenyl sulfone, carbon tetrabromide, tris(2,3-dibromopropyl)phosphate, trichloroacetamide, amyl iodide, isobutyl iodide, 1,1,1-trichloro-2,2-bis(p-chlorophenyl)ethane, hexachloroethane, and chlorinated triazine compounds.

Each amount of the coloring substance and the color former is preferably 0.01 to 10% by mass in the photosensitive resin composition. This amount is preferably 0.01% by mass or more from the viewpoint of obtaining recognizable, sufficient coloring (color-forming) properties and is preferably 10% by mass or less from the viewpoint of having the contrast between exposed and unexposed parts and maintaining storage stability.

For improving the heat stability and storage stability of the photosensitive resin composition of the present invention, it is further preferred that the photosensitive resin composition should contain at least one or more compound(s) selected from the group consisting of radical polymerization inhibitors, benzotriazoles, and carboxybenzotriazoles.

Examples of such radical polymerization inhibitors include p-methoxyphenol, hydroquinone, pyrogallol, naphthylamine, tert-butylcatechol, cuprous chloride, 2,6-di-tert-butyl-p-cresol, 2,2′-methylenebis(4-methyl-6-tert-butylphenol), 2,2′-methylenebis(4-ethyl-6-tert-butylphenol), nitrosophenylhydroxyamine aluminum salts, and diphenylnitrosamine.

Moreover, examples of the benzotriazoles include 1,2,3-benzotriazole, 1-chloro-1,2,3-benzotriazole, bis(N-2-ethylhexyl)aminomethylene-1,2,3-benzotriazole, bis(N-2-ethylhexyl)aminomethylene-1,2,3-tolyltriazole, and bis(N-2-hydroxyethyl)aminomethylene-1,2,3-benzotriazole.

Moreover, examples of the carboxybenzotriazoles include 4-carboxy-1,2,3-benzotriazole, 5-carboxy-1,2,3-benzotriazole, N-(N,N-di-2-ethylhexyl)aminomethylenecarboxybenzotriazole, N-(N,N-di-2-hydroxyethyl)aminomethylenecarboxybenzotriazole, and N-(N,N-di-2-ethylhexyl)aminoethylenecarboxybenzotriazole.

The total amount of the radical polymerization inhibitors, benzotriazoles, and carboxybenzotriazoles added is preferably 0.01 to 3% by mass, more preferably 0.05 to 1% by mass. This amount is preferably 0.01% by mass or more from the viewpoint of imparting storage stability to the photosensitive resin composition and is more preferably 3% by mass or less from the viewpoint of maintaining sensitivity.

The photosensitive resin composition of the present invention may optionally contain an additive such as a plasticizer. Examples of such an additive include glycol esters such as polyethylene glycol, polypropylene glycol, polyoxypropylene polyoxyethylene ether, polyoxyethylene monomethyl ether, polyoxypropylene monomethyl ether, polyoxyethylene polyoxypropylene monomethyl ether, polyoxyethylene monoethyl ether, polyoxypropylene monoethyl ether, and polyoxyethylene polyoxypropylene monoethyl ether, phthalic acid esters such as diethyl phthalate, o-toluenesulfonic acid amide, p-toluenesulfonic acid amide, tributyl citrate, triethyl citrate, triethyl acetylcitrate, tri-n-propyl acetylcitrate, and tri-n-butyl acetylcitrate.

The amount of the additive such as a plasticizer contained in the photosensitive resin composition is preferably 5 to 50% by mass, more preferably 5 to 30% by mass. This amount is preferably 5% by mass or more from the viewpoint of suppressing delay in developing time and imparting flexibility to a cured film and is preferably 50% by mass or less from the viewpoint of suppressing insufficient curing and cold flow.

### <Photosensitive Resin Composition Liquid>

The photosensitive resin composition of the present invention may be used as a photosensitive resin composition liquid supplemented with a solvent. Examples of a preferable solvent include ketones typified by methyl ethyl ketone (MEK) and alcohols such as methanol, ethanol, and isopropyl alcohol. It is preferred that the solvent should be added to the photosensitive resin composition so that the photosensitive resin composition liquid has a viscosity of 500 to 4000 mPa·sec. at 25° C.

### <Photosensitive Resin Layered Film>

A photosensitive resin layered film of the present invention comprises a photosensitive resin layer and a support for supporting the layer and may optionally have a protective layer on the surface of the photosensitive resin layer on the side opposite to the support.

It is desired that the support used here should be a transparent support through which light irradiated from an exposure light source is transmitted. Examples of such a support include polyethylene terephthalate films, polyvinyl alcohol films, polyvinyl chloride films, vinyl chloride copolymer films, polyvinylidene chloride films, vinylidene chloride copolymer films, methyl polymethacrylate copolymer films, polystyrene films, polyacrylonitrile films, styrene copolymer films, polyamide films, and cellulose derivative films. These films may be stretched for use, if necessary. Those having a haze of 5 or less are preferable. A film having a thinner thickness is more advantageous in terms of image forming properties and cost performance. A film having a thickness of 10 to 30 μm is preferably used, for example, because strength needs to be maintained.

Moreover, the important characteristic of the protective layer used in the photosensitive resin layered film is in that the protective layer can be stripped easily because of its adhesion to the photosensitive resin layer sufficiently smaller than the adhesion of the support to the photosensitive resin layer. For example, polyethylene and polypropylene films can be used preferably as the protective layer. Alternatively, a film excellent in strippability shown in Japanese Patent Application Laid-Open No. 59-202457 can be used. The film thickness of the protective layer is preferably 10 to 100 μm, more preferably 10 to 50 μm.

The thickness of the photosensitive resin layer in the photosensitive resin layered film of the present invention is preferably 5 to 100 μm, more preferably 7 to 60 μm. A photosensitive resin layer having a thinner thickness provides more improved resolution. Alternatively, a photosensitive resin layer having a larger thickness provides more improved film strength. Therefore, the thickness can be selected appropriately according to applications.

A conventionally known method can be adopted as a method for preparing the photosensitive resin layered film of the present invention by laminating the support, the photosensitive resin layer, and the optional protective layer in order.

For example, the photosensitive resin composition used in the photosensitive resin layer is made into the photosensitive resin composition liquid. This photosensitive resin composition liquid is initially applied onto the support by use of a bar coater or a roll coater and dried to laminate the photosensitive resin layer comprising the photosensitive resin composition onto the support.

Subsequently, the protective layer can be laminated optionally onto the photosensitive resin layer to thereby prepare the photosensitive resin layered film.

### <Method for Forming Resist Pattern>

A resist pattern using the photosensitive resin layered film of the present invention can be formed by steps comprising a lamination step, an exposure step, and a development step. One example of a specific method will be shown.

First, the lamination step is performed using a laminator. When the photosensitive resin layered film has a protective layer, the protective layer is stripped, and then, the photosensitive resin layer is heat-pressed and laminated onto a base plate surface using a laminator. In this case, the photosensitive resin layer may be laminated onto either side of the base plate or may be laminated onto both sides of the base plate, if necessary. In this procedure, a heating temperature is generally 40 to 160° C. Moreover, the heat pressing is performed twice or more times to thereby improve the adhesion of the obtained resist pattern to the base plate. In this procedure, the pressing may be performed using a two-stage laminator equipped with tandem rolls or may be performed by repetitively passing the photosensitive resin layer on the base plate through a roll.

Next, the exposure step is performed using an exposure machine. If necessary, the support is stripped, and exposure is performed with active light through a photomask. An exposure dose is determined according to the illuminance of a light source and an exposure time. The exposure dose may be measured using an actinometer.

At the exposure step, a maskless exposure method may be used. In the maskless exposure, exposure is performed onto a base plate using a direct writing apparatus without the use of a photomask. A semiconductor laser, an ultra-high-pressure mercury lamp, or the like having a wavelength of 350 to 410 nm is used as a light source. A writing pattern is controlled by a computer. In this case, an exposure dose is determined according to the illuminance of a light source and the moving speed of the base plate.

Next, the development step is performed using a developing apparatus. After exposure, the support is removed if it is present on the photosensitive resin layer. Subsequently, the unexposed parts are removed by development using a developing solution made of an aqueous alkaline solution to obtain a resist image. An aqueous solution of, for example, Na₂CO₃ or K₂CO₃ is preferable as the aqueous alkaline solution. These developing solutions are selected according to the characteristics of the photosensitive resin layer. An aqueous solution of Na₂CO₃ having a concentration of 0.2 to 2% by mass is generally used. A surfactant, an anti-foaming agent, a small amount of an organic solvent for promoting development, and so on may be mixed into the aqueous alkaline solution. It is preferred that the temperature of the developing solution at the development step should be kept at a constant temperature within the range of 20 to 40° C.

The resist pattern is obtained by the aforementioned steps. In some cases, a heating step at 100 to 300° C. can further be performed. Chemical resistance can be improved further by performing this heating step. A furnace based on a hot-air, infrared, or far-infrared manner can be used in the heating.

### <Method for Producing Printed Wiring Board>

A method for producing a printed wiring board according to the present invention is performed through the following steps after forming a resist pattern on a copper clad laminate as a baste plate or a flexible base plate by the method for forming a resist pattern.

First, the step of using a known method such as an etching or plating method to form a conductor pattern on the copper surface of the base plate exposed by development is performed.

Then, a stripping step of stripping the resist pattern from the base plate with an aqueous solution more strongly alkaline than the developing solution is performed to obtain a desired printed wiring board. The aqueous alkaline solution for stripping (hereinafter, also referred to as a “stripping solution”) is not particularly limited. An aqueous solution of NaOH or KOH having a concentration of 2 to 5% by mass is generally used. A small amount of a water-soluble solvent may also be added to the stripping solution. It is preferred that the temperature of the stripping solution at the stripping step should range from 40 to 70° C.

### <Method for Producing Lead Frame>

A method for producing a lead frame according to the present invention is performed through the following steps after forming a resist pattern on a metal plate such as copper, a copper alloy, or an iron-based alloy as a base plate by the above mentioned method for forming a resist pattern.

First, the step of etching the base plate exposed by development to form a conductor pattern is performed.

Then, a stripping step of stripping the resist pattern is performed in the same way as in the above mentioned method for producing a printed wiring board to obtain a desired lead frame.

### <Method for Producing Semiconductor Package>

A method for producing a semiconductor package according to the present invention is performed through the following steps after forming a resist pattern on a wafer with a completely formed LSI circuit as a base plate by the above mentioned method for forming a resist pattern.

First, a step of providing columnar plating such as copper or solder onto an opening exposed by development to form a conductor pattern is performed. Then, a stripping step of stripping the resist pattern is performed in the same way as in the above mentioned method for producing a printed wiring board. Furthermore, the step of removing a thin metal layer in regions other than the columnar plating by etching is performed to obtain a desired semiconductor package.

### <Method for Producing Substrate Having Concavo-Convex Pattern>

The resist pattern formed by the method for forming a resist pattern can be used as a protective mask member for processing a base plate by a sandblast method.

Examples of the base plate include glass, silicon wafers, amorphous silicon, polycrystalline silicon, ceramics, sapphire, and metal materials. A resist pattern is formed on these base plates such as glass in the same way as in the above mentioned method for forming a resist pattern. Then, a sandblast treatment step of spraying blast materials onto the formed resist pattern to produce a cut of desired depth and a stripping step of removing, from the base plate, the resist pattern portion remaining on the base plate using an alkaline stripping solution or the like can be performed to produce a substrate having a fine concavo-convex pattern on the base plate. Known blast materials are used at the sandblast treatment step. For example, fine particles of approximately 2 to 100 μm in size, such as SiC, SiO₂, Al₂O₃, CaCO₃, ZrO, glass, or stainless are used.

The method mentioned above for producing a substrate having a concavo-convex pattern by a sandblast method can be used in the production of a partition for a flat panel display, the processing of a glass cap for organic EL, the drilling process of a silicon wafer, and processing for erecting pins in a ceramic, etc. Moreover, this method can be utilized in the production of electrodes in a ferroelectric film and in a metal material layer selected from the group consisting of noble metals, noble metal alloys, high melting point metals, and high melting point metal compounds.

### EXAMPLES

Hereinafter, examples of the embodiments of the present invention will be described more specifically with reference to Examples.

A method for preparing evaluation samples of Examples and Comparative Examples will be described first. Subsequently, a method for evaluating the obtained samples and evaluation results thereof will be shown.

1. Preparation of Evaluation Sample

Photosensitive resin layered films of Examples and Comparative Examples were prepared as follows:

### <Preparation of Photosensitive Resin Layered Film>

A photosensitive resin composition having the composition shown in Table 1 and a solvent were well stirred and mixed to prepare a photosensitive resin composition liquid. This photosensitive resin composition liquid was uniformly applied onto the surface of a polyethylene terephthalate film of 16 μm in thickness as a support by use of a bar coater and dried for 3 minutes in a drier at 95° C. to form a photosensitive resin layer. The photosensitive resin layer had a thickness of 25 μm.

Subsequently, a polyethylene film of 23 μm in thickness was laminated as a protective layer onto the surface of the photosensitive resin layer on the polyethylene terephthalate film-unlaminated side to obtain a photosensitive resin layered film.

The names of material constituents in the photosensitive resin composition liquid represented by abbreviations in Table 1 are shown in Table 2. Comparative Examples 1 to 4 are compositions free from a pyrazoline constituent (d) used in the present invention. Moreover, Comparative Examples 5 and 6 are compositions free from hexaarylbisimidazole used in the present invention.

TABLE 1

| | | Ex. 1 | Ex. 2 | Ex. 3 | Ex. 4 | Ex. 5 | Ex. 6 | Ex. 7 |
|---|---|---|---|---|---|---|---|---|
| Photosensitive resin composition | P-1 | 173.33 | 173.33 | 173.33 | 173.33 | 173.33 | 173.33 | 173.33 |
| (part by mass) | M-1 | 20 | 20 | 20 | | | | |
| | M-2 | 15 | 15 | 15 | 1515 | 15 | 15 | 15 |
| | M-3 | 10 | 10 | 10 | 10 | 10 | 10 | 10 |
| | M-4 | | | | 20 | | | |
| | M-5 | | | | | 20 | 20 | 20 |
| | A-1 | | | | | | | |
| | A-2 | 2 | 2 | 2 | 2 | 2 | 2 | 2 |
| | A-3 | | | | | | | |
| | A-4 | | | | | | | |
| | A-5 | 0.3 | 0.1 | | 0.1 | 0.1 | 0.1 | |
| | A-6 | | | 0.3 | | | 0.1 | |
| | A-7 | | | | | | | 0.3 |
| | B-1 | 0.04 | 0.04 | 0.04 | 0.04 | 0.04 | 0.04 | 0.04 |
| | B-2 | 0.5 | 0.5 | 0.5 | 0.5 | 0.5 | 0.5 | 0.5 |
| Compatibility | (rank) | good | good | good | good | good | good | good |
| Sensitivity | (21st) | 8 | 8 | 8 | 8 | 8 | 8 | 8 |
| Exposure dose | (mJ/cm²/rank) | 80/excellent | 120/good | 60/excellent | 120/good | 120/good | 80/excellent | 100/excellent |
| Resolution | (μm/rank) | 22/good | 18/excellent | 22/good | 18/excellent | 16/excellent | 20/excellent | 20/excellent |
| Adhesion | (μm/rank) | 20/excellent | 20/excellent | 22/good | 18/excellent | 18/excellent | 22/good | 20/excellent |
| Storage stability | (rank) | good | good | good | good | good | good | good |

| | | Comp. Ex. 1 | Comp. Ex. 2 | Comp. Ex. 3 | Comp. Ex. 4 | Comp. Ex. 5 | Comp. Ex. 6 |
|---|---|---|---|---|---|---|---|
| Photosensitive resin composition | P-1 | 173.33 | 173.33 | 173.33 | 173.33 | 173.33 | 173.33 |
| (part by mass) | M-1 | 20 | 20 | 20 | 20 | 20 | 20 |
| | M-2 | 15 | 15 | 15 | 15 | 15 | 15 |
| | M-3 | 10 | 10 | 10 | 10 | 10 | 10 |
| | M-4 | | | | | | |
| | M-5 | | | | | | |
| | A-1 | | 0.1 | | | | |
| | A-2 | 2 | 2 | 2 | 2 | | |
| | A-3 | | | 0.3 | | | |
| | A-4 | | | | 0.3 | | |
| | A-5 | | | | | 0.1 | |
| | A-6 | | | | | | 0.1 |
| | A-7 | | | | | | |
| | B-1 | 0.04 | 0.04 | 0.04 | 0.04 | 0.04 | 0.04 |
| | B-2 | 0.5 | 0.5 | 0.5 | 0.5 | 0.5 | 0.5 |
| Compatibility | (rank) | good | good | poor | poor | good | good |
| Sensitivity | (21st) | —* | 8 | —*2 | —*2 | —* | —* |
| Exposure dose | (mJ/cm²/rank) | >200/poor | 360/poor | —*2 | —*2 | >200/poor | >200/poor |
| Resolution | (μm/rank) | —* | 25/good | —*2 | —*2 | —* | —* |
| Adhesion | (μm/rank) | —* | 25/good | —*2 | —*2 | —* | —* |
| Storage stability | (rank) | good | good | —*2 | —*2 | good | good |

*a resist is not sufficiently photocured, and a resist line is not farmed.
*2: undissolved matters remain on the coated surface, and evaluation cannot be achieved.

TABLE 2

| Symbol | Constituent |
|---|---|
| P-1 | Methyl ethyl ketone solution containing 30% by mass of a |
| | thermoplastic copolymer having the composition of methyl |
| | methacrylate/methacrylic acid/n-butyl acrylate (ratio by mass: |
| | 65/25/10) and having an acid equivalent of 344 and a |
| | weight-average molecular weight of 120000 |
| M-1 | Urethanized product of hexamethylene diisocyanate and |
| | pentapropylene glycol monomethacrylate |
| M-2 | α,ω-dimethacrylate of triethylene glycol dodecapropylene |
| | glycol triethylene glycol |
| M-3 | 4-nonylphenylheptaethylene glycol dipropylene glycol acrylate |
| | (manufactured by NOF Corp., LS-100A) |
| M-4 | (2,2-bis{4-(methacryloxypentaethoxy)phenyl}propane |
| | (manufactured by Shin-Nakamura Chemical Co., |
| | Ltd, trade name: BPE-500) |
| M-5 | (2,2-bis{4-(methacryloxypentaethoxy)cyclohexyl}propane |
| A-1 | 4,4′-bis(diethylamino)benzophenone |
| A-2 | 2,2′-bis(2-chlorophenyl)-4,4′,5,5′-tetraphenyl-1,1′-bisimidazole |
| A-3 | 1,5-diphenyl-3-styryl-pyrazoline |
| A-4 | 1-phenyl-3-(4-methyl-styryl)-5-(4-methyl-phenyl)-pyrazoline |
| A-5 | 1-phenyl-3-(4-tert-butyl-styryl)-5-(4-tert-butyl-phenyl)- |
| | pyrazoline |
| A-6 | 1-(4-(benzoxazol-2-yl)phenyl)-3-(4-tert-butyl-styryl)-5- |
| | (4-tert-butyl-phenyl)-pyrazoline |
| A-7 | 1-phenyl-3-(4-N,N-diethyl-styryl)-5-(4-N,N-diethyl-phenyl)- |
| | pyrazoline |
| B-1 | Malachite green |
| B-2 | Leuco crystal violet |

### <Surface Cleaning and Conditioning of Base Plate>

A copper clad laminate of 1.6 mm in thickness laminated with a 35-μm rolled copper film was used as a base plate for sensitivity and resolution evaluation. The surface thereof was subjected to wet buff-roll polishing (manufactured by 3M, Scotch-Brite (registered trademark) HD#600; passed twice).

### <Lamination>

While the polyethylene film was stripped from the photosensitive resin layered film, the surface thereof was cleaned and conditioned. The resulting photosensitive resin layer was laminated onto the copper clad laminate preheated to 60° C. by use of a hot roll laminator (manufactured by Asahi Kasei EMD Corp., AL-70) at a roll temperature of 105° C. An air pressure was set to 0.35 MPa, and a lamination speed was set to 1.5 m/min.

### <Exposure>

Exposure was performed in an exposure dose giving the 8th step in a step tablet using a direct writing exposure apparatus (manufactured by Hitachi Via Mechanics, Ltd., DI exposure machine DE-1 AH, light source: GaN blue-violet diode, dominant wavelength: 407±3 nm) according to sensitivity evaluation described below.

### <Development>

The polyethylene terephthalate film was stripped. Then, an aqueous solution of 1% by mass of Na₂CO₃ at 30° C. was sprayed for a predetermined time to remove the unexposed parts of the photosensitive resin layer by dissolution. In this procedure, the minimum time required to completely dissolve the unexposed parts of the photosensitive resin layer was defined as the minimum developing time.

2. Evaluation Method

(1) Compatibility Test

The photosensitive resin composition liquid having the composition shown in Table 1 was well stirred and mixed. This photosensitive resin composition liquid was uniformly applied onto the surface of a polyethylene terephthalate film of 16 μm in thickness as a support by use of a bar coater and dried for 3 minutes in a drier at 95° C. to form a photosensitive resin layer. Then, the coated surface was visually observed and ranked as follows:

Good: the coated surface is uniform

Poor: undissolved matters are deposited on the coated surface

(2) Sensitivity Evaluation

After a lapse of 15 minutes after lamination, the base plate for sensitivity and resolution evaluation was exposed using a 21-step tablet manufactured by Stouffer with luminance varying on a scale of 1 to 21 from transparency to black. After exposure, development was performed for a developing time twice the minimum developing time. The base plate was ranked as follows according to an exposure dose giving the 8th step in a step tablet by which the resist film completely remained:

Excellent: the exposure dose is 100 mJ/cm² or less

Good: the exposure dose exceeds 100 mJ/cm² and is 150 mJ/cm² or less

Fair: the exposure dose exceeds 150 mJ/cm² and is 200 mJ/cm² or less

Poor: the exposure dose exceeds 200 mJ/cm²

(3) Resolution Evaluation

After a lapse of 15 minutes after lamination, the base plate for sensitivity and resolution evaluation was exposed via a line pattern mask at the width ratio of the exposed parts to the unexposed parts of 1:1. Development was performed for a developing time twice the minimum developing time. The minimum mask line width in which cured resist lines were normally formed was used as a value of resolution.

Excellent: the value of resolution is 20 μm or less

Good: the value of resolution exceeds 20 μm and is 30 μm or less

Fair: the value of resolution exceeds 30 μm

(4) Adhesion Evaluation

After a lapse of 15 minutes after lamination, the base plate for sensitivity and resolution evaluation was exposed via a line pattern mask at the width ratio of the exposed parts to the unexposed parts of 1:1. Development was performed for a developing time twice the minimum developing time. The minimum mask line width in which cured resist lines were normally formed was used as a value of adhesion.

Excellent: the value of adhesion is 20 μm or less

Good: the value of adhesion exceeds 20 μm and is 30 μm or less

Fair: the value of adhesion exceeds 30 μm

(5) Storage Stability Evaluation

The polyethylene film was stripped from the photosensitive resin layered film. The light transmittance at a wavelength of 600 nm was measured using an UV-vis spectrometer (manufactured by Shimadzu Corp., UV-240). In this procedure, the same polyethylene terephthalate film as used in the photosensitive resin layered film was placed on the reference side of the spectrometer to cancel a transmittance derived from the polyethylene terephthalate film. The transmittance of the photosensitive resin layered film stored at a temperature of 50° C. and humidity of 60% for 3 days was compared with the transmittance of the same photosensitive resin layered film stored at a temperature of 23° C. and humidity of 50% for 3 days. The photosensitive resin layered film was ranked according to the difference thereof as follows:

Good: the difference in transmittance at 600 nm is less than ±10%

Poor: the difference in transmittance at 600 nm is ±10% or more

3. Evaluation Results

The evaluation results of Examples and Comparative Examples are shown in Table 1.

### INDUSTRIAL APPLICABILITY

The present invention can be utilized in the production of a printed wiring board, the production of a lead frame for mounting an IC chip thereon, and the precision processing of a metallic foil such as the production of a metal mask, the production of a package such as BGA or CSP, the production of a tape substrate such as COF or TAB, the production of a semiconductor bump, the production of a partition for a flat panel display, such as an ITO electrode, an address electrode, or an electromagnetic shield, and a method for producing a substrate having a concavo-convex pattern by a sandblast method.

1-11. (canceled)

12. A photosensitive resin composition characterized by comprising: (a) 20 to 90% by mass of a thermoplastic copolymer comprising an α,β-unsaturated carboxyl group containing monomer as a copolymerization constituent and having an acid equivalent of 100 to 600 and a weight-average molecular weight of 5000 to 500000; (b) 5 to 75% by mass of an addition polymerizable monomer having at least one terminal ethylenic unsaturated group; (c) 0.01 to 30% by mass of a photopolymerization initiator containing a hexaarylbisimidazole; and (d) 0.001 to 10% by mass of a pyrazoline compound represented by the following general formula (I): 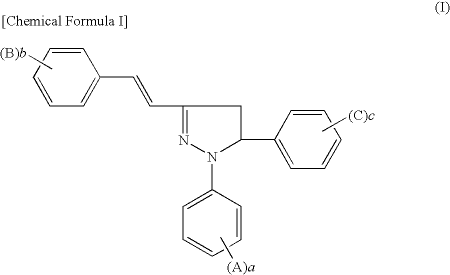
(wherein B and C each independently represent a linear or branched alkyl group having 3 or more carbon atoms, or NR₂ (R represents a hydrogen atom or an alkyl group); A represents a substituent selected from the group consisting of an aryl group, a heterocyclic group; and a linear or branched alkyl group having 3 or more carbon atoms; a represents 0 or 1, and b and c represent b=c=1).

13. The photosensitive resin composition according to claim 12, characterized in that the pyrazoline compound (d) comprises 1-phenyl-3-(4-tert-butyl-styryl)-5-(4-tert-butyl-phenyl)-pyrazoline or 1-(4-benzoxazol-2-yl)phenyl)-3-(4-tert-butyl-styryl)-5-(4-tert-butyl-phenyl)-pyrazoline, or a mixture thereof.

14. The photosensitive resin composition according to claim 12, characterized in that the pyrazoline compound (d) comprises 1-(4-benzoxazol-2-yl)phenyl)-3-(4-tert-butyl-styryl)-5-(4-tert-butyl-phenyl)-pyrazoline.

15. The photosensitive resin composition according to any one of claims 12 to 14, characterized in that the addition polymerizable monomer (b) contains a compound represented by the following general formula (II) or a compound represented by the following general formula (III), or a mixture thereof: 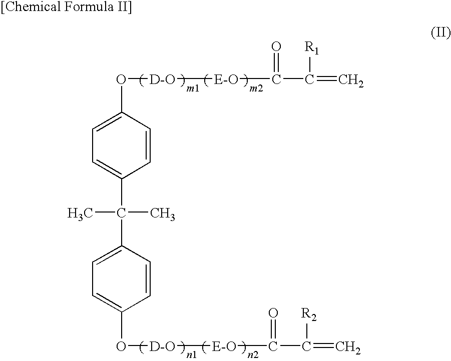
(wherein each of R₁ and R₂, which may be the same or different, represents H or CH₃; each of D and E, which may be the same or different, represents an alkylene group having 2 to 4 carbon atoms, and when D and E are different, -(D-O)— and -(E-O)—repeating units may have a block or random structure; and each of m1, m2, n1, and n2 represents 0 or a positive integer, and the sum of m1, m2, n1, and n2 is 2 to 30); and 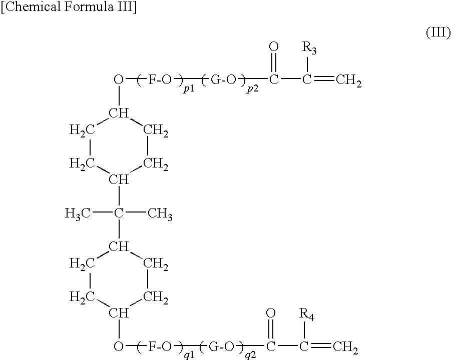
(wherein each of R₃ and R₄, which may be the same or different, represents H or CH₃; each of F and G, which may be the same or different, represents an alkylene group having 2 to 4 carbon atoms, and when F and G are different, —(F—O)— and -(G-O)—repeating units may have a block or random structure; and each of p1, p2, q1, and q2 represents 0 or a positive integer, and the sum of p1, p2, q1, and q2 is 2 to 30).

16. A photosensitive resin layered film obtained by laminating a photosensitive resin composition according to any one of claims 12 to 14 onto a support.

17. A photosensitive resin layered film obtained by laminating a photosensitive resin composition according to claim 15 onto a support.

18. A method for forming a resist pattern, comprising a lamination step of forming a photosensitive resin layer on a base plate using a photosensitive resin layered film according to claim 16, an exposure step, and a development step.

19. The method for forming a resist pattern according to claim 18, characterized in that at the exposure step, the exposure is performed by direct writing.

20. A method for producing a printed wiring board, comprising the step of etching or plating a base plate having a resist pattern formed by a method according to claim 18.

21. A method for producing a lead frame, comprising the step of etching a base plate having a resist pattern formed by a method according to claim 18.

22. A method for producing a semiconductor package, comprising the step of etching or plating a base plate having a resist pattern formed by a method according to claim 18.

23. A method for producing a substrate having a concavo-convex pattern, comprising the step of processing, by sandblast, a base plate having a resist pattern formed by a method according to claim 18.

24. A method for forming a resist pattern, comprising a lamination step of forming a photosensitive resin layer on a base plate using a photosensitive resin layered film according to claim 17, an exposure step, and a development step.

25. The method for forming a resist pattern according to claim 24, characterized in that at the exposure step, the exposure is performed by direct writing.

26. A method for producing a printed wiring board, comprising the step of etching or plating a base plate having a resist pattern formed by a method according to claim 24.

27. A method for producing a lead frame, comprising the step of etching a base plate having a resist pattern formed by a method according to claim 24.

28. A method for producing a semiconductor package, comprising the step of etching or plating a base plate having a resist pattern formed by a method according to claim 24.

29. A method for producing a substrate having a concavo-convex pattern, comprising the step of processing, by sandblast, a base plate having a resist pattern formed by a method according to claim 24.

30. A method for producing a printed wiring board, comprising the step of etching or plating a base plate having a resist pattern formed by a method according to claim 19.

31. A method for producing a lead frame, comprising the step of etching a base plate having a resist pattern formed by a method according to claim 19.

32. A method for producing a semiconductor package, comprising the step of etching or plating a base plate having a resist pattern formed by a method according to claim 19.

33. A method for producing a substrate having a concavo-convex pattern, comprising the step of processing, by sandblast, a base plate having a resist pattern formed by a method according to claim 19.
